(19) United States
(12) Patent Application Publication
(10) Pub. No.: US 2009/0090886 A1
(43) Pub. Date: Apr. 9, 2009

(54) Single-crystalline hematite rhombohedra and magnetic nanocomposites of iron and magnetite and methods of making same

(75) Inventors: Stanislaus S. Wong, Stony Brook, NY (US); Tae-Jin Park, Davis, CA (US)

Correspondence Address: HOFFMANN & BARON, LLP, 6900 JERICHO TURNPIKE, SYOSSET, NY, 11791, US

(73) Assignee: The research Foundation of State University New York.

(21) Appl. No.: 11/973,815

(22) Filed: Oct. 9, 2007

(51) Int. Cl. H01F 1/04; C01G 49/02; C30B 28/02

(52) U.S. Cl. 252/62.55; 423/632; 117/7

(57) ABSTRACT

The present invention relates to nanostructures, in particular to hematite rhombohedra and iron/magnetite nanocomposites, and methods of making same.

This invention was made with Government support from the U.S. Department of Energy under contract number DE-AC02-98CH10886 for facility support, the National Science Foundation under CAREER award Grant No. DMR-0348239, and the donors of the American Chemical Society Petroleum Research Fund. The Government has certain rights in this invention.

### BACKGROUND OF THE INVENTION

Monodisperse inorganic mesoscopic structures with well-defined size, shape, chemical composition, and crystallinity have attracted extensive synthetic attention because of their novel morphology-dependent properties and their relevant applications including but not limited to biosensing, catalysis, optics, and data storage. (Alivisatos, A. P. Science 1996, 271, 933.; Ahmadi et al, Science 1996, 272, 1924; Cui et al., Science 2001, 291, 851; Sun et al., Science 2002, 298, 2176; Sun et al., Science 2000, 287, 1989; Bruchez et al., Science 1998, 281, 2013; Wang et al., Science 2001, 293, 1455; Xia et al., Adv. Mater. 2003, 15, 353.)

In particular, the generation of nanostructured magnetic materials with controllable shape and size in large quantities is of significant importance due to the potential applications, ranging from ferrofluids, advanced magnetic materials, catalysts, colored pigments, high-density magnetic recording media, to medical diagnostic equipment. (Hyeon, T. Chem. Commun. 2003, 927.) Much of the existing research though has focused on the synthesis and morphological organization of phase-pure nanosized building blocks such as nanoparticles. The fabrication of nanosized composites, such as core-shell, coaxial cable, as well as one and two-dimensional structures, has not been as investigated as comprehensively. (Yang et al., J. Am. Chem. Soc. 2005, 127, 270; Park et al, Angew. Chem. Int. Ed. 2005, 44, 2; Liu et al., J. Am. Chem. Soc. 2005, 127, 6; Kim et al., Nano Lett. 2005, 5, 1987; Zhang et al., J. Am. Chem. Soc. 2005, 127, 13492; Tzitzios et al., Adv. Mater. 2005, 17, 2188; Zeng et al., S, Nano Lett. 2004, 4, 187; Teng et al., J. Am. Chem. Soc. 2003, 125, 14559.)

Among magnetic materials, the Fe/Fe₃O₄ composite system has specifically attracted considerable attention due to its favorable magnetoelectric and transport (including high conductivity) properties. (Yang et al., J. Phys. D: Appl. Phys. 2005, 38, 1215; Zeng et al., Nature 2002, 420, 395; Bonetti et al., J. Appl. Phys. 2001, 89, 1806; Ding et al., Scr. Mater. 1996, 35, 1307.) Moreover, this composite has been shown to produce a novel and active heterogeneous Fenton system, important in the oxidation of organic contaminants. (Moura et al., Chemosphere 2005, 60, 1118.)

The synthetic routes associated with the formation of these composites follow a “bottom up” strategy, wherein growth of the resulting structure occurs through assembly of constituent molecular species. Such routes do not allow for predictive control of the size and shape of the resulting materials.

Additionally, considerable efforts have been expended in the generation of nanoscale structures of hematite, using a variety of techniques such as chemical precipitation, sol-gel techniques, hydrothermal approaches, forced hydrolysis, and solid-state reaction, to name a representative few. (Wang et al., Chem. Lett. 2005, 34, 184; Matijevic, E. Chem. Mater. 1993, 5, 412; Ocana et al., Adv. Mater. 1995, 7, 212; Wong et al., J. Phys. Chem. B 2001, 105, 599; Frandsen et al., Phys. Rev. Lett. 2005, 94, 027202; Jin et al., Adv. Mater. 2004, 16, 48; Woo et al., Adv. Mater. 2003, 15, 1761; Dong et al., J. Mater. Chem. 2002, 12, 1676; Sugimoto et al., Colloids Surf. A 1998, 134, 265; Jing et al., Wu, S. Mater. Lett. 2005, 59, 804; Wang et al., J. Mater. Chem. 2004, 14, 905; Jones et al., CrystEngComm 2003, 5, 159; Raming et al., J. Colloid Interface Sci. 2002, 249, 346; Chen et al., J. Phys. Chem. B 2002, 106, 8539; Hansen et al., Phys. Rev. B 2000, 62, 1124; Zboril et al., Hyp. Interact. 2002, 139/140, 597; Xu et al., J. Appl. Phys. 2002, 91, 4611; Zysler et al., J. Magn. Magn. Mater. 2001, 224, 39; Shen et al., Chem. Lett. 2004, 33, 1128; Fu et al.)

Hematite is thought to be catalytic in the oxidation of chlorinated pollutants in groundwater and is found in the clay fraction of tropical and sub-tropical soils, giving them their pink bright red hue. Bacteria in surface waters are known to catalyze the oxidation of magnetite (Fe₃O₄) to hematite. (Brown et al., Geochimica et Cosmochimica Acta 1997, 61, 3341.) Because of its high stability, relatively low cost, and n-type semiconducting properties with a small bandgap (2.1 eV), α-Fe₂O₃ has been associated with applications ranging from gas sensing, catalysis, solar energy conversion, to pigmentation. (Chen et al., Adv. Mater. 2005, 17, 582; Gondal et al., Chem. Phys. Lett. 2004, 385, 111; Ohmori et al., Phys. Chem. Chem. Phys. 2000, 2, 3519.)

The methods of making nanoscale structures of hematite (e.g., the aforementioned solution-phase approaches) involve the use of organometallic precursors, surfactants, and solvents in either potentially hazardous or rather complicated protocols. Thus, there is a need to develop an environmentally friendly and efficient methodology to synthesize iron oxides.

Additionally, the shape of a nanoparticle, which determines the exposed crystallographic surface (and its corresponding surface energy) enclosing the particle, have a dramatic effect on its properties. As examples, the relative intensities of X-ray diffraction peaks, the positions of bands in optical spectra, and the magnitude of sublimation energies of a wide variety of materials, including Au and Ag₂S, are intrinsically coupled with particle morphology (such as icosahedra, cubes, and tetrahedra). With hematite in particular, changes in microhardness, electrical conductivity (i.e. mobility enhancement), as well as in superparamagnetic blocking behavior are strongly associated with its physical and structural characteristics. (Zysler et al., J. Magn. Magn. Mater. 2001, 224, 39; Stevenson et al., J. Eur. Ceram. Soc. 2002, 22, 1137; Miller et al., Thin Solid Films 2004, 466, 307.)

As another relevant manifestation of the significance of shape for magnetic nanoparticles, shape anisotropy and crystalline anisotropy have a profound influence on their intrinsic magnetic properties (such as coercivity). (Hyeon, T. Chem. Commun. 2003, 927.) In fact, the magnetic anisotropy (i.e. higher coercivity) present in rod-shaped magnetic particles, which by contrast is not observed in symmetrically-shaped spheres or cubes, has been exploited in the use of these acicular particles for commercial magnetic recording media.

However, the prior art methods of making nanoscale iron oxide structures do not allow for the predictive control of size and shape. Thus, there is a need to develop an efficient methodology by which to synthesize iron oxide nanostructures with reproducible dimensions.

### BRIEF DESCRIPTION OF THE DRAWINGS

FIG. 1. Schematic illustration of the generation of single-crystalline hematite rhombohedra (as well as other hematite structural motifs) and corresponding Fe/Fe₃O₄ nanocomposites.

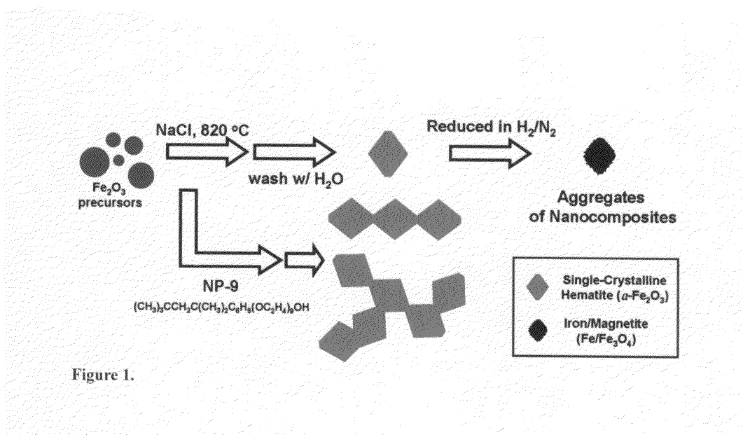

FIG. 2. XRD patterns of as-prepared α-Fe₂O₃ rhombohedra particles (a), and of α-Fe₂O₃ from the JCPDS #33-0664 database standard (b).

FIG. 3. (A) TEM image of as-prepared α-Fe₂O₃ rhombohedral particles. (B) SAED pattern of an α-Fe₂O₃ rhombohedron. (C) EDS of an α-Fe₂O₃ rhombohedron. The Cu and C peaks originate from the TEM grid. (D) HRTEM image of a typical portion of an α-Fe₂O₃ rhombohedron.

FIG. 4. SEM images of α-Fe₂O₃ structures prepared using a molten salt method with 1:40 (A), 2:40 (B), 3:40 (C), and 6:40 (D) molar ratios of Fe₂O₃ to NaCl precursors, respectively. For the purpose of shape control, the precursors in (B), (C), and (D) were added to 2 ml of NP-9, a nonionic surfactant. Insets show higher-magnification images of individual hematite particles.

FIG. 5. Histograms of size distributions of as-prepared hematite structures. Parameters for each structure are given in terms of width (A) and length (B). Molar ratios of reagents are given in the following order—Fe₂O₃:NaCl:NP-9 surfactant.

FIG. 6. SEM images of α-Fe₂O₃ structures prepared from molar ratios of 3:40 (A), and 6:40 (B) of Fe₂O₃:NaCl precursors, without the presence of surfactant.

FIG. 7. (A) Lower and (B) correspondingly higher magnification SEM image of as-transformed magnetic composites of Fe/Fe₃O₄. (C) TEM image of a cluster of individual Fe/Fe₃O₄ structures. (D) XRD pattern of as-transformed Fe/Fe₃O₄ structures. Asterisks indicate XRD peaks from Fe.

FIG. 8. (A) TEM image of a typical individual magnetic composite of iron and magnetite. Inset shows the corresponding SAED pattern of a Fe/Fe₃O₄ rhombohedron. (B) Higher magnification image of the composite of Fe/Fe₃O₄. (C) An enlarged portion of the assembled nanostructure of Fe and Fe₃O₄, as delineated by the black square in (B). (D) A HRTEM image of a typical lattice spacing of a Fe₃O₄ structure. (E) An EDS spectra obtained from an individual Fe/Fe₃O₄ rhombohedron. The Cu and C peaks originate from the TEM grid.

FIG. 9. (A) Hysteresis loop at room temperature of as-transformed Fe/Fe₃O₄ composites. Inset shows the enlarged portion of the hysteresis loop revealing the coercivity of the Fe/Fe₃O₄ composite. (B) Temperature dependence of the magnetic susceptibility for Fe/Fe₃O₄ composite, showing zero field cooling (ZFC, closed circle) and field cooling (FC, closed square) curves, with an applied magnetic field set at 200 Oe.

FIG. 10. Histograms of size (widths and lengths, respectively) distributions for as-prepared hematite particles derived from commercial precursors. Molar ratios of Fe₂O₃:NaCl:NP-9 surfactant are 1:40:0 for (A) and (B); 1:40:6 for (C) and (D); 2:40:6 for (E) and (F); 3:40:6 for (G) and (H); and 6:40:6 for (I) and (J).

FIG. 11. SEM image of α-Fe₂O₃ structures prepared from a molar ratio of 1:40:6 of Fe₂O₃:NaCl:NP-9 precursors. Inset shows a higher magnification image of the product.

FIG. 12. TEM images of α-Fe₂O₃ structures prepared from molar ratios of 3:40 (A), and 6:40 (B) of Fe₂O₃:NaCl precursors, in the presence of NP9 surfactant. Insets show representative SAED images.

FIG. 13. Comparative SEM images of hematite rhombohedra (A) and of the magnetic composites of Fe and Fe₃O₄ (B).

### SUMMARY OF INVENTION

In one aspect, the present invention provides single-crystalline hematite rhombohedron wherein the rhombohedron is at least about 90%, preferably 95%, free of defects and/or dislocations. The single-crystalline hematite rhombohedron is at least 95% free amorphous materials and/or impurities. Typically, the rhombohedra have an aspect ratio of about 0.5 to about 5. The single-crystalline hematite rhombohedron can be isolated or part of a plurality of substantially monodisperse single crystalline hematite rhombohedra.

In another aspect, the present invention provides a method of making single-crystalline hematite rhombohedra. The method comprises (a) mixing Fe₂O₃ nanopowder and a salt to form a precursor mixture, wherein the ratio of the Fe₂O₃ nanopowder to the salt is about 0.5:40 to about 10:40; and (b) heating said precursor mixture at about 500 to about 1000° C. to provide single-crystalline hematite rhombohedra. The rhombohedra typically have an average aspect ratio of about 0.5 to about 2. Preferably, the method further comprising sonicating the precursor mixture before heating.

In another aspect, the present invention provides a method of making single-crystalline hematite rhombohedra. The method comprises (a) mixing Fe₂O₃ nanopowder and a salt to form a precursor mixture; (b) adding surfactant to the precursor mixture; and (c) heating said precursor mixture at about 500 to about 1000° C. to provide single-crystalline hematite rhombohedra. As the relative amount of the Fe₂O₃ nanopowder to surfactant increases, the average aspect ratio of the rhombohedra increases nonlinearly.

Preferably, the ratio of Fe₂O₃ nanopowder:salt:surfactant is about 0.5:40:6 to about 10:40:6. The ratio of about 0.5:40:6 to about 1.5:40:6 yields rhombohedra with an average aspect ratio of about 1.5 to about 1.9. The ratio of about 1.5:40:6 to about 2.4:40:6 yields rhombohedra with an average aspect ratio of about 1.9 to about 2.4. The ratio of about 2.4:40:6 to about 4.5:40:6 yields rhombohedra with an average aspect ratio of about 2.4 to about 3.3. The ratio of about 4.5:40:6 to about 10:40:6 yields rhombohedra with an average aspect ratio of about 3.3 to about 5.

In another aspect, the present invention provides a crystalline rhombohedral nanocomposite of Fe and Fe₃O₄. Preferably, the relative amount Fe₃O₄ to Fe is about 25:75. The crystalline rhombohedral nanocomposite can be isolated or part of a plurality of substantially monodisperse rhombohedral nanocomposites. In one embodiment, the plurality of substantially monodisperse crystalline rhombohedral nanocomposites have an average aspect ratio of about 0.5 to about 5.

In another aspect, the invention provides a method of making substantially monodisperse nanocrystalline rhombohedral composites of Fe and Fe₃O₄. The method comprises (a) providing a hematite precursor; and (b) heating the hematite precursor at about 200 to about 500° C. in the presence of a reductive gas to make nanocrystalline composites of Fe and Fe₃O₄.

In one embodiment, the hematite precursor is a substantially monodisperse single crystalline hematite rhombohedra made by a method comprising (a) mixing Fe₂O₃ nanopowder and a salt to form a precursor mixture, wherein the ratio of the Fe₂O₃ nanopowder to the salt is about 0.5:40 to about 10:40; and (b) heating said precursor mixture at about 500 to about 1000° C. to provide single crystalline hematite rhombohedra.

In another embodiment, the hematite precursor is single crystalline hematite rhombohedra made by a method comprising (a) mixing Fe₂O₃ nanopowder and a salt to form a precursor mixture, (b) adding surfactant to the precursor mixture; (c) heating said precursor mixture at about 500 to about 1000° C. to provide single-crystalline hematite rhombohedra, wherein as the relative amount of the Fe₂O₃ nanopowder increases, the average aspect ratio of the rhombohedra increases nonlinearly.

The advantages of the present methods for the synthesis of iron oxide nanostructures include their environmental friendliness, simplicity, relative non-toxicity, facility of use, generalizable and versatility. Because of these advantages, the methods are suitable for the large-scale preparation of important iron oxides. Additionally, the methods of the present invention allow for predictive and reproducible control over the size, shape and crystallinity of the resulting structures.

### DETAILED DESCRIPTION OF THE INVENTION

The present invention relates to nanostructures, in particular to hematite rhombohedra and iron/magnetite nanocomposites, and methods of making same. Single Crystalline Nanoscale Hematite Rhombohedra In one aspect, the present invention provides single crystalline hematite rhombohedra (i.e., α-Fe₂O₃). These rhombohedra are submicron-sized or nanoscale-sized. The hematite rhombohedra have substantially corundum structure.

The nanoscale hematite rhombohedra of the invention are crystalline and solid. Preferably, the nanostructures are at least 90% free, more preferably at least 95% free, most preferably at least 99% free, and optimally virtually completely free of defects and/or dislocations. As defined in this specification, defects are irregularities in the crystal lattice (i.e., intrinsic defects). Some examples of defects include a non-alignment of crystallites, an orientational disorder (e.g., of molecules or ions), vacant sites with the migrated atom at the surface (Schottky defect), vacant sites with an interstitial atom (Frenkel defects), point defects, grain boundary defects, and non-stoichiometry of the crystal. An example of a dislocation is a line defect in a crystal lattice.

Additionally, the nanoscale hematite rhombohedra of the invention are preferably at least 90% free, more preferably at least 95% free, most preferably at least 99% free, and optimally virtually completely free of amorphous materials and/or impurities. Examples of amorphous materials include organic surfactant molecular groups, such as bis(2-ethylhexyl)sulphosuccinate, undecylic acid, sodium dodecyl sulfate (SDS), Triton X-100, decylamine, or double-hydrophilic block copolymers, which are present on the surfaces of prior art nanostructures. Examples of impurities include an element different from the elements of the crystalline structure and a vacancy.

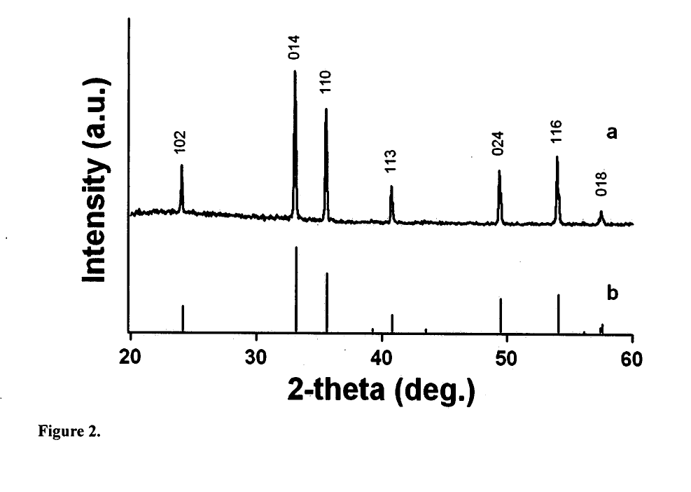

The crystallinity and purity of the hematite rhombohedra can be examined using powder XRD measurements. As can be seen in FIG. 2, the observed pattern of the collected powder displayed all of the expected peaks with very few, if any, impurity peaks.

A single-crystalline hematite rhombohedron of the present invention typically has an aspect ratio of about 0.5 to about 5, more typically from about 1.0 to about 4, and most typically about 2 to about 3.

A single-crystalline hematite rhombohedron of the present invention typically has a width of about 100 nm to about 1000 nm, more typically from about 250 to about 800, and most typically about 400 to about 600.

A single-crystalline hematite rhombohedron of the present invention typically has length of about 200 nm to about 2500 nm, more typically from about 500 to about 2000, and most typically about 1000 to about 1500.

The present invention also provides a plurality of substantially monodisperse single crystalline hematite rhombohedra. “Substantially monodisperse” means at least 90%, more preferably at least 95%, most preferably at least 99%, and optimally virtually all, of the rhombohedra in the plurality has an aspect ratio which is within at least about 1.0 standard deviation of the mean aspect ratio.

A single-crystalline hematite rhombohedron of the present invention can be part of a plurality of substantially monodisperse single crystalline hematite rhombohedra, or can be in isolated form.

### Methods of Making Single Crystalline Nanoscale Hematite Rhombohedra

In another aspect of the present invention, methods of making single crystalline hematite rhombohedra are provided. All the types of rhombohedra described above can be made by these methods.

Typically, the single-crystalline hematite rhombohedra of the present invention can have aspect ratios of about 0.5 to about 5. The resulting aspect ratio can be controlled by the particular reaction conditions and reagents used to form the rhombohedra, as described below. Accordingly, in one embodiment of the present invention, methods of controllably producing single-crystalline hematite rhombohedra of particular aspect ratios are provided.

Single-Crystalline Hematite Rhombohedra with Relatively Low Aspect Ratio

In one embodiment, a method of making single-crystalline hematite rhombohedra having an average aspect ratio of about 0.5 to about 2, more typically of about 1 to about 1.5, is provided. The method comprises mixing Fe₂O₃ nanopowder and a salt to form a precursor mixture. The Fe₂O₃ powder can be polydisperse, monodisperse, polycrystalline, single crystalline, amorphous, or combinations thereof.

The ratio of the Fe₂O₃ nanopowder to the salt is about 0.5:40 to about 10:40, more typically about 1:40 to about 5:40, most typically about 1.5:40 to about 2.5:40.

The precursor mixture is heated at about 500 to about 1000° C., more preferably at about 700 to about 900° C., most preferably at about 800 to about 850° C., to provide single-crystalline hematite rhombohedra.

The salt used can be any salt. Examples of suitable salts include NaCl, KCl, NaOH/KOH, NaNO₃, and NaNO₃/NaCl.

In a preferred embodiment, prior to the heating step, the precursor mixture is sonicated.

Preferably, the prepared single-crystalline hematite rhombohedra are brought to room temperature and washed. The rhombohedra can be collected by any means known in the art (e.g., centrifugation).

Single-Crystalline Hematite Rhombohedra with Elongated Structures

In another embodiment, methods of making single-crystalline hematite rhombohedra with elongated structures are provided. These rhombohedra have an average aspect ratio of about 1.5 to about 5.0, more typically of about 2.0 to about 3.5.

The method comprises mixing Fe₂O₃ nanopowder and a salt to form a precursor mixture. The Fe₂O₃ powder can be polydisperse, monodisperse, polycrystalline, single crystalline or amorphous, or combinations thereof. Surfactant is added to the precursor mixture.

Preferably, the ratio of Fe₂O₃ nanopowder:salt:surfactant is about 0.5:40:6 to about 10:40:6. The precursor mixture is heated at about 500 to about 1000° C., more preferably at about 700 to about 900° C., most preferably at about 800 to about 850° C., to provide single-crystalline hematite rhombohedra.

Any non-ionic surfactant can be used. Most nonionic surfactants are composed of linear or nonyl-phenol alcohols or fatty acids. The function of surfactants in this class is to reduce surface tension and dispersibility.

Non-ionic surfactants are known in the art. Examples of non-ionic surfactants can be found, for instance, in “Non-ionic Surfactants: Organic Chemistry,” edited by Nico M. van Os, published by Marcel Dekker (1998), and “Non-ionic Surfactants: Chemical Analysis (Surfactant Science Series, Vol. 19)” by John Cross, published by Marcel Dekker (Oct. 1, 1986). Some non-ionic surfactants can be divided into classes depending on the type of hydrophilic group appearing in the surfactants.

Two classes of non-ionic surfactants that comprise poly(ethylene oxide) groups as their hydrophilic groups are alcohol ethoxylates and the alkylphenol ethoxylates. Examples of non-ionic surfactants of these classes include tetraethylene glycol monododecyl ether; polyoxyethylene 23 glycol monododecyl ether; polyethylenoxide-polypropylenoxide (PEO-PPO) block-copolymers (such as the commercially available PEO-PPO-PEO triblockcopolymers, called Synperonics F108 and F127), polyoxyethylene alkylphenols; polyoxyethylene alcohols; polyoxyethylene esters of fatty acids; polyoxyethylene mercaptans; and polyoxyethylene alkylamines.

Another class of non-ionic surfactants is the alkyl polyglycosides. In these molecules, the hydrophilic group is a sugar molecule, such as a polysaccharide, disaccharide, trisaccharide, maltose, etc. Preferably, the polyglycosides have one or two sugar groups in their chains. Examples of non-ionic surfactants of this class include alkyl glucoside and a glucose ester.

Another class of non-ionic surfactants is sorbitan ester surfactants. Examples of non-ionic surfactants of this class include polysorbate 20 (i.e. polyoxyethylene (20) sorbitan monolaurate, sold as Tween 20™); polysorbate 60 (i.e. polyoxyethylene (60) sorbitan monostearate); polysorbate 80 (i.e. polyoxyethylene (20) sorbitan monooleate); and polysorbate 65 (i.e. polyoxyethylene (20) sorbitan tristearate).

Examples of other suitable surfactants include NP-9 surfactant (Aldrich, polyoxyethylene(9)nonylphenyl ether), sodium dodecyl sulfate (SDS), dodecylbenzene sulphonate (SBDS), Triton X-100, X-77 (UAP), Induce (Helena), Activator 90 (UAP), Triton Ag 98 (Rhone-Poulenc) and R-11 (Wilfarm), Pluronic Acid, bis(2-ethylhexyl)sulphosuccinate, undecylic acid, decylamine, and double-hydrophilic block copolymers.

The salt used can be any salt. Examples of suitable salts include NaCl, KCl, NaOH/KOH, NaNO₃, and NaNO₃/NaCl.

As the relative amount of the Fe₂O₃ nanopowder is increased, the average aspect ratio of the rhombohedra increases nonlinearly. Examples of how varying the relative amount of the Fe₂O₃ nanopowder affects the average aspect ratio of the rhombohedra follow. When the ratio of Fe₂O₃ nanopowder:salt:surfactant is about 0.5:40:6 to about 1.5:40:6, the resulting rhombohedra have an average aspect ratio of about 1.5 to about 1.9. When the ratio of Fe₂O₃ nanopowder:salt:surfactant is about 1.5:40:6 to about 2.4:40:6, the resulting rhombohedra have an average aspect ratio of about 1.9 to about 2.4. When the ratio of Fe₂O₃ nanopowder:salt:surfactant is about 2.4:40:6 to about 4.5:40:6, the resulting rhombohedra have an average aspect ratio of about 2.4 to about 3.3. When the ratio of Fe₂O₃ nanopowder:salt:surfactant is about 4.5:40:6 to about 10:40:6, the resulting rhombohedra have an average aspect ratio of about 3.3 to about 5.

Additionally, for a constant amount of Fe₂O₃ nanopowder, the ratio of salt:surfactant can be about 100:1 to about 1:1, wherein as the relative amount of surfactant increases, the aspect ratio of the resulting rhombohedra decreases.

In a preferred embodiment, prior to the heating step, the precursor mixture is sonicated.

Preferably, the prepared single-crystalline hematite rhombohedra are brought to room temperature and washed. The rhombohedra can be collected by any means known in the art (e.g., centrifugation).

### Crystalline Rhombohedral Nanocomposites of Fe and Fe₃O₄

In one aspect, the present invention provides crystalline rhombohedral nanocomposites of Fe and magnetite (i.e., Fe₃O₄). A single rhombohedral nanocomposite consists essentially of Fe and Fe₃O₄.

The Fe and Fe₃O₄ can be dispersed within a single rhombohedral nanocomposite in domain regions. The Fe domain regions and the Fe₃O₄ domain regions are adjacent to one another within a rhombohedron. The domain regions are each typically about 1 to about 50 nm, more typically from about 10 to about 20 nm, most typically about 11 to about 15 nm in area.

The nanocomposites of the invention are crystalline and solid. Preferably, the nanocomposites are at least 90% free, more preferably at least 95% free, most preferably at least 99% free, and optimally virtually completely free of defects and/or dislocations. Additionally, the nanocomposites of the invention are preferably at least 90% free, more preferably at least 95% free, most preferably at least 99% free, and optimally virtually completely free of amorphous materials and/or impurities.

The invention also provides a substantially monodisperse plurality (i.e., assembly) of crystalline rhombohedral nanocomposites of Fe and magnetite (i.e., Fe₃O₄).

“Substantially monodisperse” means at least 90%, more preferably at least 95%, most preferably at least 99%, and optimally virtually all of the nanocomposites of a plurality consists of nanostructures with a rhombohedral shape and consists of Fe and Fe₃O₄.

In some embodiments, “substantially monodisperse” also means that at least 90%, more preferably at least 95%, most preferably at least 99%, and optimally virtually all of the rhombohedra in the nanocomposite plurality have an average aspect ratio which is within at least 1.0 standard deviation of the mean aspect ratio.

The nanocomposites have hard and soft magnetic phases juxtaposed within one discrete, anisotropic structure. Typically, Fe₃O₄ is the soft phase and Fe is the hard phase. The relative amount of Fe to Fe₃O₄ can be from about 1:99 to about 99:1. Typically, the dimension of the soft phase is made to be smaller than that of the hard phase. For example, the amount of Fe₃O₄ to Fe can be about 25:75 to about 40:60, more typically about 30:70 to about 33:67.

The nanocomposites typically exhibit strong ferromagnetic behavior. Typically, there is some degree of magnetic exchange coupling between the Fe and magnetite domains.

The structural inhomogeneity of the Fe/magnetite nanocomposites has a strong influence on its saturation magnetization (i.e., M_{S}). Depending on the relative amount of Fe, the nanocomposite can exhibit M_{S} of about 50 to about 250 emu/g. The M_{S} increases as the relative amount of Fe in the composite increases. As an example, when the amount of Fe₃O₄ to Fe is about 33:67, the M_{S} is about 100 emu/g.

The Fe/magnetite nanocomposite possesses a relatively high Verwey transition temperature. Depending on the relative amount of Fe, the nanocomposite can exhibit Verwey transition temperature of about 100 K to about 200 K. The Verwey transition temperature increases as the relative amount of Fe in the composite increases. As an example, when the amount of Fe₃O₄ to Fe is about 33:67, the Verwey transition temperature is about 135 K.

The Fe/magnetite nanocomposites possess a relatively high coercivity. Coercivity is the intensity of the applied magnetic field required to reduce the magnetization of that material to zero after the magnetization of the sample has been driven to saturation. The nanocomposite can exhibit coercivity of about 100 to about 500 Oe. As an example, when the amount of Fe₃O₄ to Fe is about 33:67, the coercivity is about 250 Oe.

### Methods of Making Crystalline Rhombohedral Nanocomposites of Fe and Fe₃O₄

In another aspect of the present invention, methods of making crystalline rhombohedral nanocomposites of Fe and Fe₃O₄ are provided. All the types of nanocomposites described above can be made by these methods.

In the methods, hematite (i.e., hematite precursor) is transformed into Fe/Fe₃O₄ nanocomposites. Any type of hematite can be used in these methods, including, for example, polydisperse or monodisperse hematite. If substantially monodisperse hematite is used, then substantially monodisperse nanocomposites are produced.

The methods comprise heating hematite at about 200 to about 500° C., more preferably at about 250 to about 450° C., most preferably at about 300 to about 400° C., in the presence of a reductive gas to provide Fe/Fe₃O₄ nanocomposites. The reductive gas can be, for example, hydrogen gas by itself, or a gasesous mixture comprising hydrogen. A gaseous mixture can be, for example, hydrogen gas in the presence of an inert gas (e.g., nitrogen gas or any of the noble gases). For example, the gasesous mixture can be about 1% H₂ to about 10% H₂ in an inert gas, e.g., about 5% H₂ in N₂.

The relative amount of Fe in the composite increases as the duration and/or temperature of the reduction reaction is increased. If the reduction reaction is run long enough, then there will be virtually only a Fe phase.

As the hematite is reduced, the reddish hue of hematite changes to the deep black of the resulting iron/magnetite composite.

In a preferred embodiment, the hematite is single crystalline hematite in the shape of rhombohedra (i.e., α-Fe₂O₃). In a highly preferred embodiment, the single crystalline hematite rhombohedra are substantially monodisperse. Methods of making substantially monodisperse single crystalline hematite rhombohedra are described above. The shape, size and aspect ratio of the starting hematite rhombohedra directly transforms into the shape, size and aspect ratio of the resulting nanocomposite.

The composites have many practical applications. For example, the relatively high coercivity indicates the applicability of these nanoscale composite magnetic structures as low-cost hard magnetic materials. The magnetically hard/soft phases can be used to tune magnetic properties by controlling the transformation conditions so as to obtain desired saturation magnetizations. The control of Verwey transition has applications associated with metallic and insulating properties.

### EXAMPLES

The Examples demonstrate the generation of distinctive structural polymorphs of hematite iron oxide from relatively polydisperse, commercially available starting precursor materials. Subsequently, these single-crystalline α-Fe₂O₃ rhombohedral structures were transformed into their magnetic nanocrystalline composite counterparts, Fe/Fe₃O₄. These samples were characterized by a number of techniques, including scanning electron microscopy (SEM), transmission electron microscopy (TEM), high-resolution TEM (HRTEM), energy-dispersive X-ray spectroscopy (EDS), selected area electron diffraction (SAED), X-ray diffraction (XRD), and superconducting quantum interference device (SQUID) measurements.

General. Specifically, commercial iron(III) oxide or Fe₂O₃ (Aldrich, polydisperse nanopowder), NP-9 surfactant (Aldrich, polyoxyethylene(9)nonylphenyl ether), and NaCl (Mallinckrodt, sodium chloride) were used as supplied. The choice of the surfactant was governed by its prior versatility in the preparation of elongated structures of metal oxides, its relative non-toxicity, and comparative facility of use. (Park et al., J. Mater. Chem. 2005, 15, 2099.) Stoichiometric amounts of Fe₂O₃, NaCl, and NP-9 were mixed (in molar ratios of 1:40:6, 2:40:6, 3:40:6, and 6:40:6, respectively, for the generation of varying structural motifs of hematite), thoroughly ground in an agate mortar, and subsequently sonicated.

In a typical synthesis of submicron-sized, single-crystalline α-Fe₂O₃ rhombohedra, 0.5 and 20 mmol of Fe₂O₃ and NaCl, respectively, were mixed thoroughly in an agate mortar. For elongated α-Fe₂O₃ structures, 1, 1.5, and 3 mmol of Fe₂O₃ along with 20 mmol of NaCl, respectively, were meticulously mixed, after which 2 ml of NP-9 was subsequently added. The resulting mixture was ground for at least 30 min prior to sonication for an additional 5 min. Identical procedures were employed for samples containing different molar ratios of initial precursors. The resulting mixture was then placed in a ceramic crucible, inserted into a quartz tube, heated at a ramp rate of 5° C. per min up to an annealing temperature at 820° C. for 3.5 h, and cooled thereafter to room temperature. As-prepared material was subsequently washed several times with distilled water, collected by centrifugation, and dried at 120° C. in a drying oven.

Hematite rhombohedra were converted to their magnetic analogues (i.e. composites of Fe/Fe₃O₄) through a reduction reaction in a flowing gaseous mixture. Briefly, the as-prepared hematite product was heated in a tube furnace at 360° C. for 5 h under a continuous flow of 5% H₂ in N₂. After the gas flow was stopped, the resulting product was subsequently heated to 240° C. for 2 h, cooled to room temperature, and then collected without further treatment.

X-Ray diffraction. Crystallographic information of as-prepared samples was obtained on a Scintag diffractometer, operating in the Bragg configuration using Cu Kα radiation (k=1.54 Å). Powder X-ray diffraction (XRD) samples were prepared by grinding products thoroughly in ethanol using a mortar and pestle, followed by loading onto glass slides, and subsequent drying in air. Diffraction patterns were collected from 10 to 80° at a scanning rate of 2°/min with a step size of 0.02°. Parameters used for slit widths and accelerating voltage were identical for all samples.

Electron Microscopy. The particle size and morphology of the resulting Fe₂O₃ as well as Fe/Fe₃O₄ products were initially characterized using a field emission scanning electron microscopy (SEM, Leo 1550) operated at accelerating voltages of 15 kV and equipped with energy dispersion X-ray spectroscopy (EDS) capabilities. Specifically, samples were deposited onto a Si wafer, which were then attached to the surface of SEM brass stubs using a copper tape. These samples were then conductively coated with gold by sputtering them for 10-20 seconds to minimize charging effects under SEM imaging conditions.

Specimens for transmission electron microscopy (TEM) and high resolution TEM (HRTEM) were obtained by drying sample droplets from an ethanolic dispersion onto a 300 mesh Cu grid coated with a lacey carbon film. Low magnification TEM images were taken at an accelerating voltage of 120 kV on a Philip CM12 instrument. High-resolution images were obtained on a JEOL 2010F HRTEM at an accelerating voltage of 200 kV. This instrument was equipped with an Oxford INCA EDS system with the potential of performing selected area electron diffraction (SAED) to further characterize individual iron oxide nanostructures.

SQUID. Magnetization measurements were obtained using an MPMS magnetometer. Powder samples of as-prepared products were pressed lightly, then loaded into a gel cap, and covered with silica wool. This was held within a uniform drinking straw, which was attached to the sample rod of the MPMS apparatus. Signals generated by measurements of an empty sample holder demonstrated that the holder assembly contributes <1% to the overall magnetic signal.

### Results and Discussion

### A. Iron Oxide Rhombohedra

The purity and crystallinity of as-prepared hematite (α-Fe₂O₃) structures were examined using powder XRD measurements (FIG. 2). It is evident that the observed pattern of the collected powder displayed all of the expected peaks emanating from the α-Fe₂O₃ structure with very few, if any, impurity peaks. In effect, diffraction peaks in FIG. 2A can be indexed to the rhombohedral structure of α-Fe₂O₃ [space group: R_{3c}] with structural parameters of a=b=5.038 Å, c=13.772 Å, a==90°, and y=120°, which are in good agreement with literature results (i.e., JCPDS #33-0664, FIG. 2B).

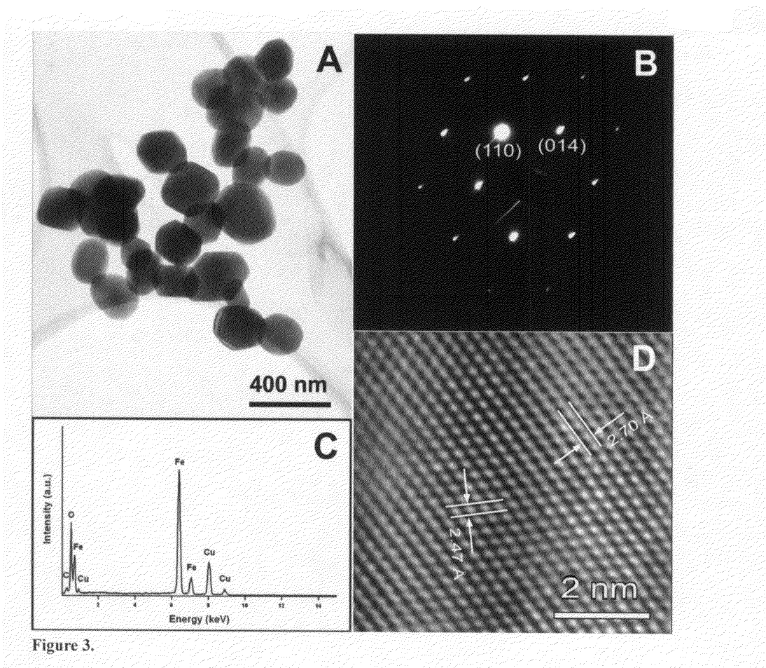

A typical TEM image of α-Fe₂O₃ rhombohedra, generated from the current molten salt method with a 1:40 molar ratio of Fe₂O₃ to NaCl, is shown in FIG. 3A. The size of the particles, which can be described in terms of the mean lengths of the shorter and longer diagonals of the rhombohedron, were measured to be 231±40 and 198±35 nm, respectively, with their aspect ratio calculated to be 1.2 on average. SAED data taken from an individual rhombohedral structure (FIG. 3B) show the presence of sharp diffraction spots indicating the formation of well-developed, single-crystalline hematite particles. It is noted that the electron diffraction patterns obtained from different positions along the same rhombohedron as well as from different rhombohedra also show similar sharp diffraction spots. In order to confirm the chemical composition of the as-prepared structures, EDS spectra (FIG. 3C) were taken at a number of selected positions of the sample. The elemental signatures obtained are identical within experimental accuracy, and essentially Fe and O were observed, as expected. The Cu and C signals arise from the TEM grid. In FIG. 3D, a HRTEM image obtained from part of an individual α-Fe₂O₃ rhombohedron is displayed so as to further confirm the single-crystalline nature of our as-prepared structures. This image shows a typical crystalline domain with interplanar spacings of about 2.70 and 2.47 Å, which are comparable with the literature values of 2.700 and 2.519 Å, which correspond to the (014) and (110) planes of the hexagonal phases of the α-Fe₂O₃ rhombohedral crystal, respectively (JCPDS #33-0664).

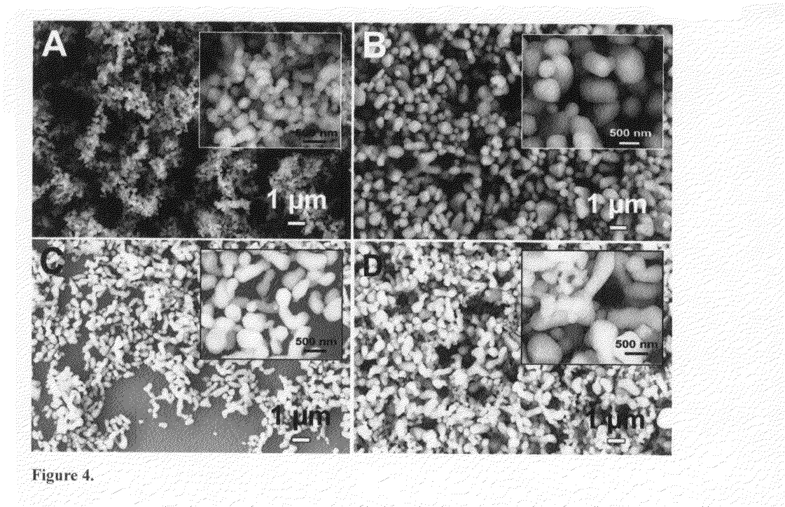

FIG. 4 shows SEM images revealing the morphologies of as-prepared α-Fe₂O₃ structures, generated from the as-described protocol. It can be observed that the α-Fe₂O₃ product, prepared using a molten salt method with a 1:40 molar ratio of Fe₂O₃ to NaCl, mainly consists of discrete rhombohedral structures with smooth surfaces (FIG. 4A). The size of the particulates is consistent with that from the TEM data discussed above. It can also be observed that the faces of the α-Fe₂O₃ rhombohedra are essentially flat though some of the corners of these structures are slightly truncated.

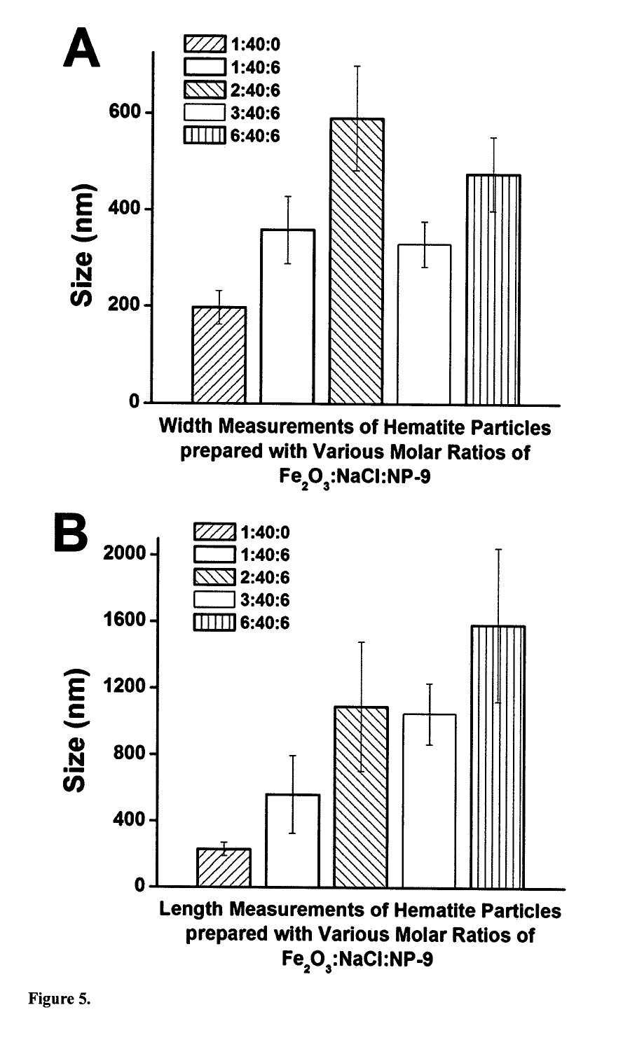

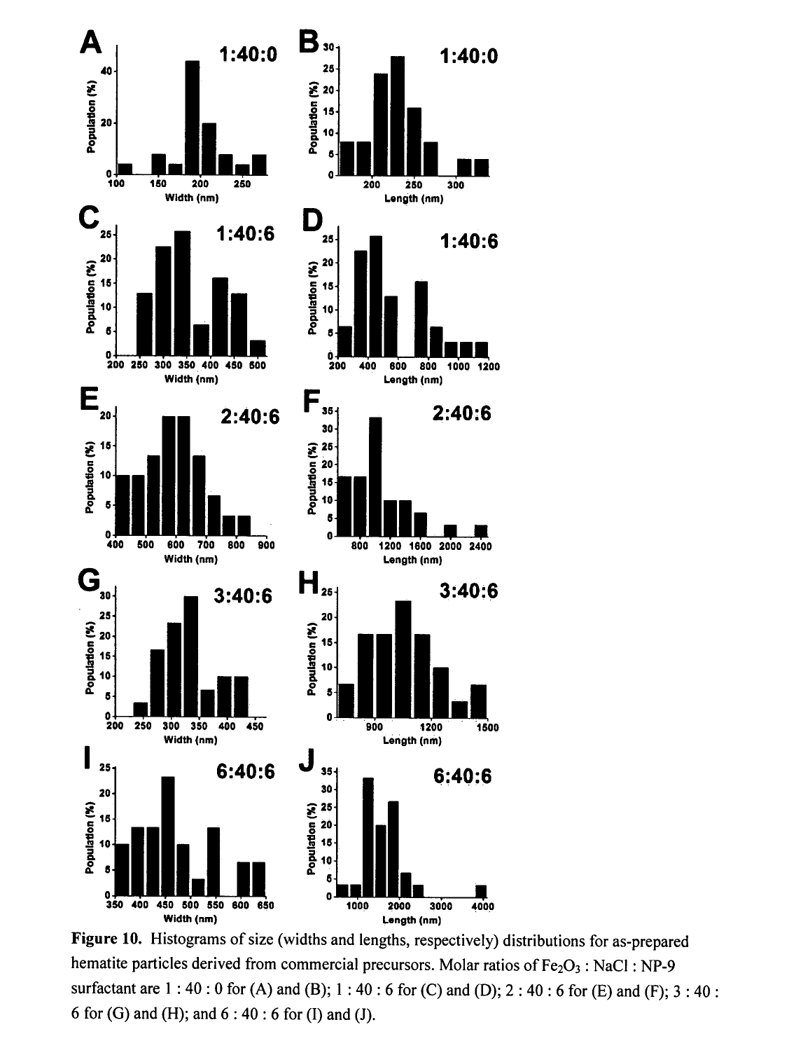

To obtain further insight into the formation of different shapes of the α-Fe₂O₃ structures, the morphologies of α-Fe₂O₃ structures generated from the precursors, derived from 2:40:6, 3:40:6, and 6:40:6 (Fe₂O₃:NaCl:NP-9) molar ratios, are shown in FIGS. 4B, 4C, and 4D, respectively. It can be observed that the shapes of α-Fe₂O₃ structures alter from their rhombohedral motifs into peanut-shaped structures. Moreover, the aspect ratio of these materials increases nonlinearly with higher molar ratios of Fe₂O₃ precursor to surfactant content in the system. In fact, for these molar ratios, the mean lengths of elongated α-Fe₂O₃ peanut-like structures are 1092±389 (B), 1050±183 (C), and 1611±565 nm (D), respectively, and their mean widths (shorter side of each structure) measure 591±108 (B), 329±47 (C), and 476±77 nm (D), respectively. Hence, their corresponding aspect ratios are 1.9, 3.3, and 3.5 for (B), (C), and (D), respectively. The aspect ratio of 3.5, observed for the product in FIG. 4D, is relatively smaller than expected. This value reflects the large degree of branching and higher overall polydispersity in the resultant iron oxide structures with increasing molar content of Fe₂O₃ and suggests the presence of numerous nucleation sites on the growing particles. Histograms of particle size (including lengths and widths) distributions for as-prepared hematite samples are shown in both FIGS. 5 and 10.

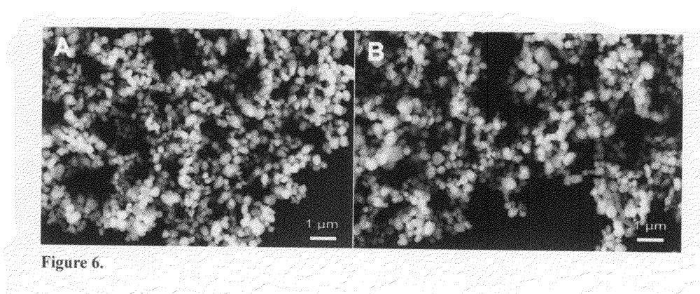

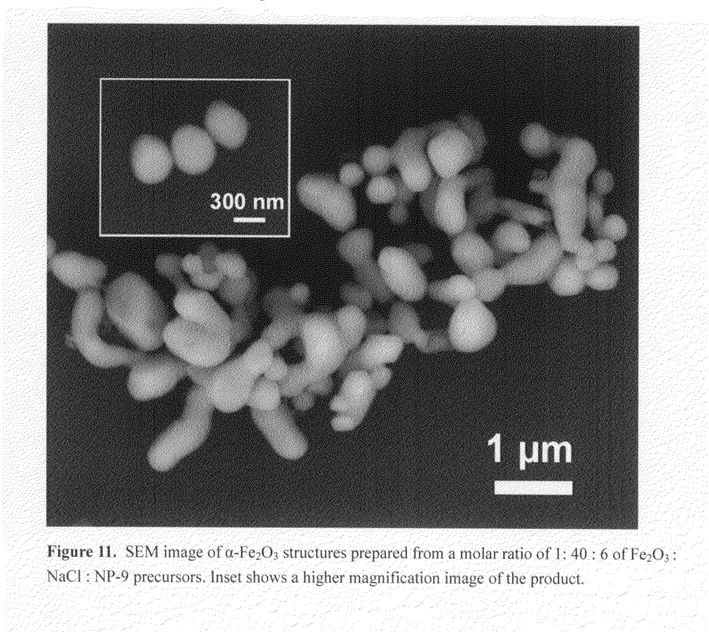

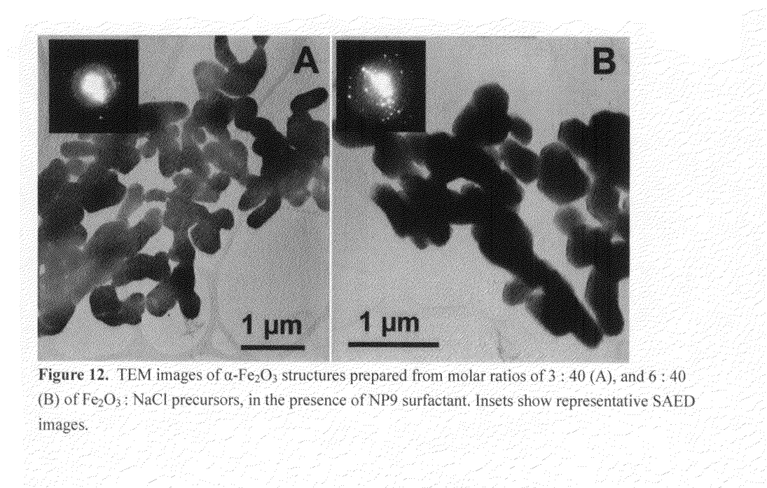

To analyze the role of surfactant in this reaction, α-Fe₂O₃ products were prepared employing identical, as-reported experimental procedures in the absence of any surfactant. The morphologies of the resultant products generated from mixtures of (a) 3:40 and (b) 6:40 molar ratios of Fe₂O₃ to NaCl precursors, respectively, are shown in FIG. 6. It is evident that all of these particles possess morphologies as well as size distributions that are consistent with the product, prepared with a molar ratio of Fe₂O₃ to NaCl precursors of 1:40 (FIGS. 4A and 5). Hence, it is apparent that surfactant, through its dispersing ability, can play a critical role adjusting the size and shape of these binary metal oxide particles. In fact, samples prepared from identical precursor ratios with and without surfactant suggest that the presence of surfactant will cause an elongation of the resulting products and skew their size distribution, as noted in FIG. 5. For instance, SEM images of hematite prepared from a mixture of a 1:40 molar ratio of Fe₂O₃ to NaCl in the presence of NP-9 are shown in FIG. 11; they are evidently more polydisperse in terms of size and shape. In fact, SEM measurements indicate that hematite particles prepared from a molar ratio of Fe₂O₃:NaCl:NP-9 equal to 1:40:6 possess mean widths of 358 (±70) nm and mean lengths of 562 (±235) nm, with a measured aspect ratio of 1.6. Nevertheless, the single-crystalline nature of all of these surfactant-treated hematite particles (FIGS. 4C and 4D) has been confirmed; associated TEM and SAED images are shown in FIG. 12.

The observations described above confirm the significant role of the surfactant combined with other experimental parameters, such as the molar ratios of precursors and the addition of salt, to collectively yield single-crystalline α-Fe₂O₃ products with predictive control of size and shape. The presence of salt is expected to decrease the overall reaction temperature. (Wiley et al., Science 1992, 255, 1093.) The liquid-like phase of the molten flux is expected to increase the mobility of its constituent components.

### B. Fe/Fe₃O₄ Composites

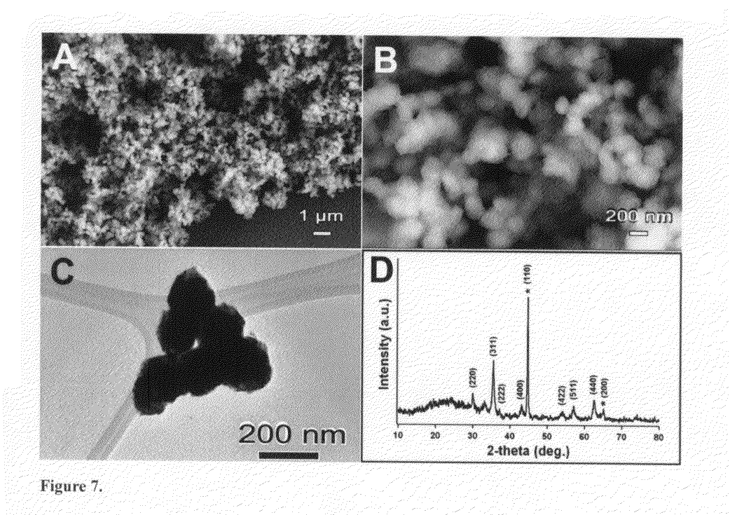

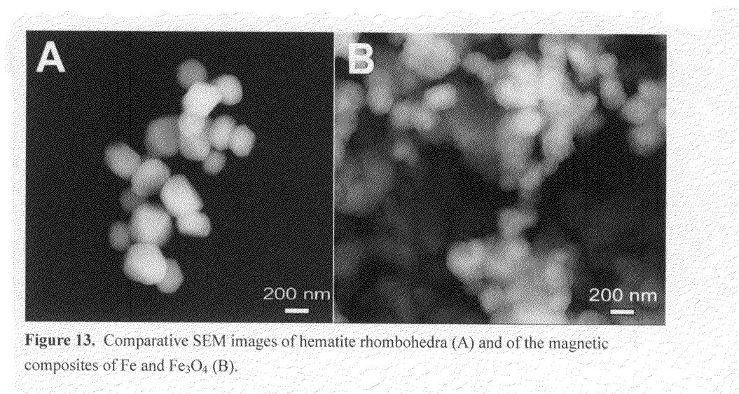

The morphologies of the resulting Fe/Fe₃O₄ composites generated from the reduction reaction are shown in FIGS. 7A and 7B. It can be observed that the size distribution, shape, and crystallinity of the resulting iron/magnetite composites are similar to those of their corresponding hematite precursors. For further comparison in their morphology, SEM images of rhombohedra of the hematite and the Fe/Fe₃O₄ composite are shown in FIG. 13. It is noted that as-generated Fe/Fe₃O₄ structures possess somewhat roughened surfaces composed of multiple domains of iron and iron oxide (FIG. 7C). Without wanting to be limited to a theory, it is hypothesized that this morphological alteration can be attributed not only to differential rates of reduction with respect to the surface and bulk of the initial nanoparticle starting materials but also to the in situ formation of domains of elemental iron and magnetite. In fact, XRD data on the resulting composites of Fe and Fe₃O₄, derived from hematite precursors, in FIG. 7D, display all of the expected peaks, in good agreement with literature results (Fe, JCPDS #06-0696; Fe₃O₄, JCPDS #19-0629), and confirm the expected chemical composition of the resulting composite Fe/Fe₃O₄ structure.

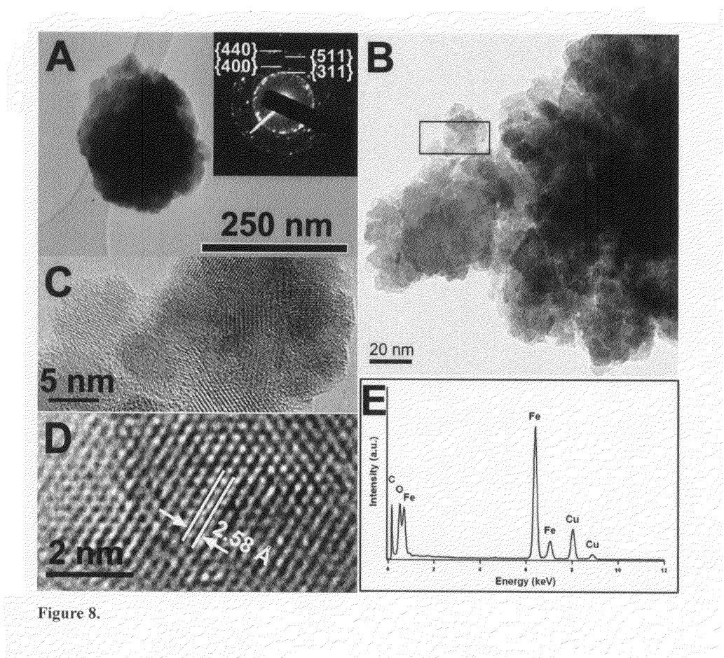

In order to further confirm the composition of the as-transformed magnetic materials, HRTEM was performed on an individual Fe/Fe₃O₄ composite shown in FIG. 8A. The SAED data taken of an individual rhombohedral structure (shown in the inset) show the presence of sharp diffraction spots and rings that could be assigned to that of Fe₃O₄. However, it is noted that the expected lattice spacing (2.0268 Å) of the {110} planes of Fe is very similar to the analogous lattice spacing (2.0993 Å) of the {400} planes of Fe₃O₄ and hence, these two distances are difficult to clearly differentiate between in the SAED pattern. Nevertheless, the electron diffraction patterns obtained from different areas of the composite structure also show similar results.

The higher magnification image of a typical Fe/Fe₃O₄ composite reveals that the surface of the rhombohedron is composed of multiple nanostructures with mean sizes of 11±3 nm (FIG. 8B). The nanostructures themselves are composed of multiple adjacent, discrete domain regions of Fe and Fe₃O₄ (FIG. 8C). In FIG. 8D, a HRTEM image obtained from a portion of an individual Fe/Fe₃O₄ composite is displayed so as to further confirm the single-crystalline nature of each individual domain of Fe and Fe₃O₄. This image shows a typical crystalline domain with an interplanar spacing of about 2.58 Å, comparable with the literature value of 2.532 Å, which corresponds to the {311} planes of the cubic phase of a Fe₃O₄ crystal (JCPDS #19-0629). In order to confirm the chemical composition of the as-prepared structures, EDS spectra (FIG. 8E) were taken at a number of selected positions along the sample. The elemental signatures obtained are identical within experimental accuracy, and essentially only Fe and O were observed, as expected. It is noted that the relative intensity of oxygen for the Fe/Fe₃O₄ composite (FIG. 258E) decreased slightly as compared with the data for the hematite precursor alone (FIG. 3C), suggestive of a lowered oxygen density in the resulting composite structure, an observation consistent with a reduction reaction having occurred. The Cu and C signals arise from the TEM grid.

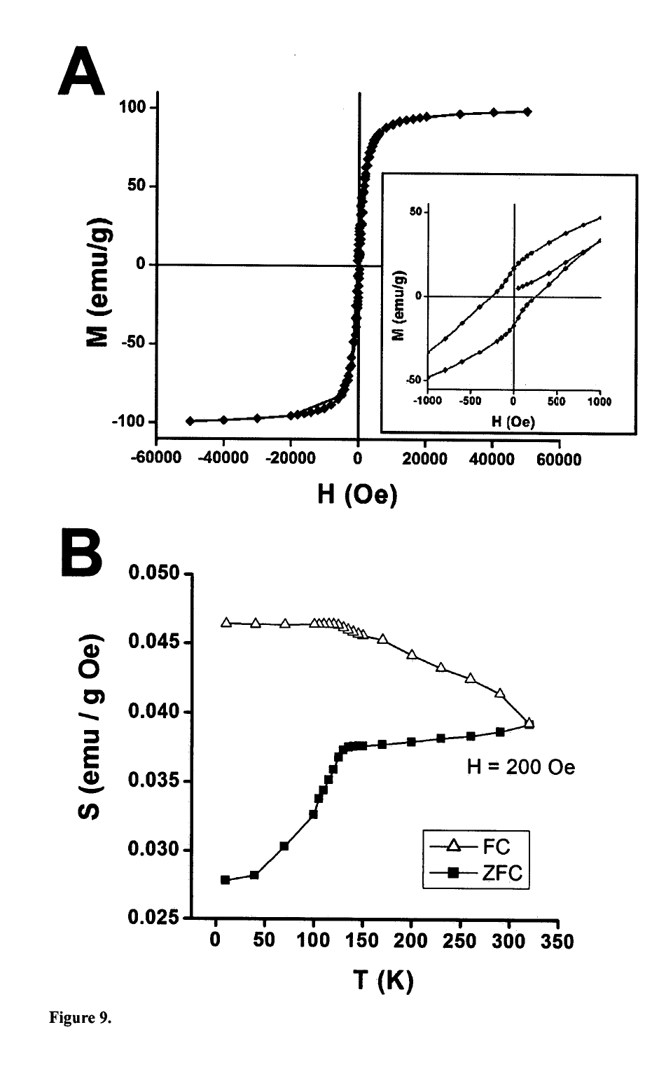

FIG. 9A shows the presence of a hysteresis loop at room temperature of the resultant nanocrystalline Fe/Fe₃O₄ composite magnetic material, revealing strong ferromagnetic behavior. These nanocomposites consist of magnetically hard and soft phases where there is some degree of magnetic exchange coupling between the Fe and magnetite domains. The magnetization curve shows a steep increase in magnetization with increasing field. The asymmetric shape of the hysteresis loop conveys two-phase behavior, implying that the dimension of the soft phase is smaller than that of the hard phase and that, furthermore, in this nanocomposite, the hard and soft phases are not able to completely switch cooperatively. Moreover, the kink at low field is related to the magnetization reversal of the soft magnetic phase, likely magnetite in this case. (Zeng et al., Nature 2002, 420, 395.) The saturation magnetization (M_{S}: ˜100 emu/g) measured for the Fe/Fe₃O₄ composite is about 20% higher than that for the magnetite phase and about 66% higher than the value of 60.1 emu/g observed for 11.5 nm-sized magnetite nanoparticles. (Ding et al., Scr. Mater. 1996, 35, 1307; Maruyama et al., Thin Solid Films 1998, 333, 203; Goya et al., J. Appl. Phys. 2003, 94, 3520.) The additional 66% increase in M_{S} is consistent with and can be attributed to the presence of an extra 67% amount of Fe (as deduced from XRD analysis) in Fe/Fe₃O₄ nanocomposites. The structural inhomogeneity of the samples has a strong influence on the M_{S} value measured. In addition, the relatively high coercivity observed (H_{C}: 250 Oe) indicates the potential applicability of these nanoscale composite magnetic structures as low-cost hard magnetic materials. The results are also comparable with data recently reported for similar structural analogues, having important applications in biomedical fields such as biomolecular separations, targeted drug delivery, cancer diagnosis and treatment, as well as magnetic resonance imaging. (Zhao et al., J. Am. Chem. Soc. 2005, 127, 8916; Deng et al., Angew. Chem. Int. Ed. 2005, 44, 2782.)

FIG. 9B shows the magnetic susceptibility of these nanoscale composites as a function of temperature at an applied field strength of 200 Oe, after zero field cooling (ZFC) and also, with field cooling (FC). The curves show the presence of the Verwey transition (Verwey, E. J. W. Nature 1939, 144, 327) at a temperature of ˜135 K, which is indicative of magnetite, arising from the ordering among Fe³⁺ and Fe²⁺ ions. The relatively higher Verwey transition temperature observed relative to pristine magnetite (˜120 K) is consistent with values recently reported for similar Fe/Fe₃O₄ composite systems (Yang et al., J. Phys. D: Appl. Phys. 2005, 38, 1215), and can be ascribed to the higher Fe content relative to that of Fe₃O₄. Hence, these results imply the usage of these materials in applications ranging from nanocomposite conductors to superconductors.

Thus, monodisperse nanocrystalline rhombohedral composites of Fe and Fe₃O₄ magnetic materials have been obtained employing a reduction reaction, in a flowing gas mixture of H₂ and N₂, of single-crystalline, submicron-sized α-Fe₂O₃ rhombohedral precursors. This synthesis is significant in that nanocomposites with hard and soft magnetic phases juxtaposed within one discrete, anisotropic structure were created. In turn, the precursor hematite rhombohedra of reproducible shape were successfully prepared using a facile, large-scale molten-salt reaction. Rhombohedra represent a high-surface-area, anisotropic formulation of an industrially important material (iron oxide) which is an active component of gas sensors, photocatalysts, and other types of catalytic materials.

Accordingly, the present invention demonstrates the generation of monodisperse assemblies of rhombohedral nanocrystalline composites of Fe and Fe₃O₄ formed from a reordering of the microstructure of single-crystalline hematite rhombohedra precursors which occurred as a product of the reduction reaction in a gaseous mixture of 5% H₂ in N₂. A significance of the work is that a nanocomposite with hard and soft magnetic phases juxtaposed within one discrete, anisotropic structure was created.

Also, demonstrated is the ability to prepare monodisperse hematite products with controlled size, shape, and monodispersity, starting from relatively inexpensive, commercially available polydisperse, polycrystalline or amorphous precursors. Single-crystalline, monodisperse nanoscale α-Fe₂O₃ rhombohedra, as well as elongated motifs of these materials, are in fact an excellent model system to demonstrate this synthetic principle. This methodology allows for control over size, shape, and chemical composition of as-prepared products using a simple, versatile, one-step, environmentally-friendly, and large-scale solid-state chemical reaction in the presence of NaCl and a nonionic surfactant.

Additionally, rhombohedra represent a high-surface-area, anisotropic formulation of an industrially important material (iron oxide) which is an active component of gas sensors, photocatalysts, and other types of catalytic materials. Moreover, α-Fe₂O₃ hematite rhombohedra present themselves as a practical, low-cost chemical precursor material to the subsequent synthesis of magnetite. The development of a facile and economically viable synthetic strategy for the synthesis of hydrophilic, biocompatible magnetic particles (including magnetite) benefits their technical use in biomedical fields, such as biomolecular separations, targeted drug delivery, tags for sensing and imaging, antitumor therapy, as well as magnetic resonance imaging. Nanostructured magnetic materials of the present invention also have applications as ferrofluids, catalysts, colored pigments, and high-density magnetic recording media.

As relevant manifestation of the significance of shape, for magnetic nanoparticles in particular such as the Fe/Fe₃O₄ composites of the present invention, shape anisotropy and crystalline anisotropy are expected to have a profound influence on their intrinsic magnetic properties (such as coercivity). In fact, the magnetic anisotropy (i.e. higher coercivity) present in rod-shaped magnetic particles, which by contrast is not observed in symmetrically-shaped spheres or cubes, has been exploited in the use of these acicular particles for commercial magnetic recording media.

1. A single-crystalline hematite rhombohedron wherein the rhombohedron is at least about 90% free of defects and/or dislocations.

2. The single-crystalline hematite rhombohedron of claim 1, wherein the rhombohedron is at least 95% free amorphous materials and/or impurities.

3. The single-crystalline hematite rhombohedron of claim 1, wherein the rhombohedron is at least about 95% free of defects and/or dislocations.

4. The single-crystalline hematite rhombohedron of claim 1 wherein the rhombohedron has an aspect ratio of about 0.5 to about 5.

5. The single-crystalline hematite rhombohedron of claim 1 wherein the rhombohedron is part of a plurality of substantially monodisperse single crystalline hematite rhombohedra.

6. A method of making single-crystalline hematite rhombohedra, the method comprising:
(a) mixing Fe₂O₃ nanopowder and a salt to form a precursor mixture, wherein the ratio of the Fe₂O₃ nanopowder to the salt is about 0.5:40 to about 10:40; and
(b) heating said precursor mixture at about 500 to about 1000° C. to provide single-crystalline hematite rhombohedra,
wherein the rhombohedra have an average aspect ratio of about 0.5 to about 2.

7. The method of claim 6 further comprising sonicating the precursor mixture before heating.

8. A method of making single-crystalline hematite rhombohedra, the method comprising:
(a) mixing Fe₂O₃ nanopowder and a salt to form a precursor mixture;
(b) adding surfactant to the precursor mixture; and
(c) heating said precursor mixture at about 500 to about 1000° C. to provide single-crystalline hematite rhombohedra,
wherein as the relative amount of the Fe₂O₃ nanopowder to surfactant increases, the average aspect ratio of the rhombohedra increases nonlinearly.

9. The method of claim 8 wherein the ratio of Fe₂O₃ nanopowder:salt:surfactant is about 0.5:40:6 to about 10:40:6.

10. The method of claim 9 wherein the ratio of about 0.5:40:6 to about 1.5:40:6 yields rhombohedra with an average aspect ratio of about 1.5 to about 1.9.

11. The method of claim 9 wherein the ratio of about 1.5:40:6 to about 2.4:40:6 yields rhombohedra with an average aspect ratio of about 1.9 to about 2.4.

12. The method of claim 9 wherein the ratio of about 2.4:40:6 to about 4.5:20:40:6 yields rhombohedra with an average aspect ratio of about 2.4 to about 3.3.

13. The method of claim 9 wherein the ratio of about 4.5:40:6 to about 10:40:6 yields rhombohedra with an average aspect ratio of about 3.3 to about 5.

14. A crystalline rhombohedral nanocomposite of Fe and Fe₃O₄.

15. The crystalline rhombohedral nanocomposite of claim 14, wherein the relative amount Fe₃O₄ to Fe is about 25:75.

16. The crystalline rhombohedral nanocomposite of claim 14 wherein the nanocomposite is part of a plurality of substantially monodisperse rhombohedral nanocomposites.

17. The plurality of substantially monodisperse crystalline rhombohedral nanocomposites of claim 16, wherein rhombohedra of the plurality have an average aspect ratio of about 0.5 to about 5.

18. A method of making substantially monodisperse nanocrystalline rhombohedral composites of Fe and Fe₃O₄, the method comprising:
(a) providing a hematite precursor; and
(b) heating the hematite precursor at about 200 to about 500° C. in the presence of a reductive gas to make nanocrystalline composites of Fe and Fe₃O₄.

19. The method of claim 18, wherein the hematite precursor is a substantially monodisperse single crystalline hematite rhombohedra made by a method comprising:
(a) mixing Fe₂O₃ nanopowder and a salt to form a precursor mixture, wherein the ratio of the Fe₂O₃ nanopowder to the salt is about 0.5:40 to about 10:40; and
(b) heating said precursor mixture at about 500 to about 1000° C. to provide single crystalline hematite rhombohedra.

20. The method of claim 18, wherein the hematite precursor is single crystalline hematite rhombohedra made by a method comprising:
(a) mixing Fe₂O₃ nanopowder and a salt to form a precursor mixture,
(b) adding surfactant to the precursor mixture;
(c) heating said precursor mixture at about 500 to about 1000° C. to provide single-crystalline hematite rhombohedra, wherein as the relative amount of the Fe₂O₃ nanopowder increases, the average aspect ratio of the rhombohedra increases nonlinearly.
